(19) United States
(12) Patent Application Publication
(10) Pub. No.: US 2018/0211975 A1
(43) Pub. Date: Jul. 26, 2018

(54) CONNECTION STRUCTURE, ARRAY SUBSTRATE, AND DISPLAY DEVICE

(71) Applicant: BOE Technology Group Co., Ltd., Beijing (CN)

(72) Inventor: Chunping LONG, Beijing (CN)

(21) Appl. No.: 15/717,376

(22) Filed: Sep. 27, 2017

(30) Foreign Application Priority Data
Jan. 24, 2017 (CN) 201720105071.7

(51) Int. Cl. H01L 27/12

(52) U.S. Cl. CPC H01L 27/124; H01L 27/1248

(57) ABSTRACT

Disclosed are a connection structure, an array substrate, and a display device. A connection structure according to some embodiments of the application includes a connection line, and at least one redundant connection line including a redundant connection section and two connection ends, wherein the redundant connection section partially overlaps with the two connection ends; the connection line is electrically connected with a first signal end and a second signal end; and the connection ends partially overlap respectively with the first signal end and the second signal end. There is at least one redundant connection line between the two signal ends of the connection line, but the redundant connection line is not connected with the two signal ends, and only if the connection line is damaged, then the redundant connection line will be electrically connected with the two signal ends.

### CROSS-REFERENCE TO RELATED APPLICATION

This application claims priority of Chinese Patent Application No. 201720105071.7, filed on Jan. 24, 2017, which is hereby incorporated by reference in its entirety.

### FIELD

The present application relates to the field of display technologies, and particularly to a connection structure, an array substrate, and a display device.

### BACKGROUND

An electronic device, e.g., a mobile phone, a computer, etc., typically includes a display for displaying information to a user. Generally the display includes a number of layers. Taking a liquid crystal display as an example, the liquid crystal display includes an upper polarization sheet layer, a lower polarization sheet layer, a color filter film layer including an array of filter sheet elements, a layer of arrays of thin film transistors and of pixel electrodes, and a liquid crystal material layer interposed between the color filter film layer and the layer of arrays. In a display including an array of pixels including light-emitting diodes, each pixel includes a light-emitting diode, and a thin film transistor for applying a signal to the light-emitting diode.

### SUMMARY

Embodiments of the applications provide a connection structure including a connection line, and at least one redundant connection line including a redundant connection section and two connection ends, wherein the redundant connection section partially overlaps with the two connection ends; the connection line is electrically connected with a first signal end and a second signal end; and the connection ends partially overlap respectively with the first signal end and the second signal end.

Embodiments of the applications further provide an array substrate. The array substrate includes the connection structure provided by some embodiments of the application.

Embodiments of the applications further provide a display device. The display device includes the array substrate provided by some embodiments of the application.

### BRIEF DESCRIPTION OF THE DRAWINGS

In order to make the technical solutions in embodiments of the application more apparent, the drawings to be used in a description of the embodiments will be briefly introduced below, and apparently the drawings to be described below are merely illustrative of some embodiments of the application, and those ordinarily skilled in the art can derive from these drawings other drawings without any inventive effort. In the drawings.

FIG. 1 is a schematic diagram of a first connection structure according to some embodiments of the application;

FIG. 2 is a schematic diagram of a second connection structure according to some embodiments of the application;

FIG. 3 is a schematic diagram of a third connection structure according to some embodiments of the application;

FIG. 4 is a schematic diagram of a fourth connection structure according to some embodiments of the application;

FIG. 5 is a schematic diagram of a fifth connection structure according to some embodiments of the application;

FIG. 6 is a schematic diagram of a sixth connection structure according to some embodiments of the application;

FIG. 7 is a schematic diagram of a seventh connection structure according to some embodiments of the application;

FIG. 8 is a schematic diagram of an eighth connection structure according to some embodiments of the application;

FIG. 9 is a schematic diagram of a ninth connection structure according to some embodiments of the application;

FIG. 10 is a schematic diagram of a tenth connection structure according to some embodiments of the application;

FIG. 11 is a schematic diagram of an eleventh connection structure according to some embodiments of the application;

FIG. 12 is a schematic diagram of a twelfth connection structure according to some embodiments of the application;

FIG. 13 is a schematic diagram of a thirteen connection structure according to some embodiments of the application;

FIG. 14 is a schematic diagram of a fourteenth connection structure according to some embodiments of the application;

FIG. 15 is a schematic diagram of a fifteenth connection structure according to some embodiments of the application;

FIG. 16 is a schematic diagram of a sixteenth connection structure according to some embodiments of the application;

FIG. 17 is a schematic diagram of a seventeenth connection structure according to some embodiments of the application;

FIG. 18 is a schematic diagram of an eighteenth connection structure according to some embodiments of the application.

### DETAILED DESCRIPTION OF THE EMBODIMENTS

In order to make the objects, the technical solutions and the advantages of the application more apparent, the application will be further described in details with reference to the drawings. Apparently the described embodiments are only a part but all of embodiments of the application. Based upon the embodiments of the application here, all of other embodiments derived by those ordinarily skilled in the art without any inventive effort shall come into the scope of the application.

Embodiments of the application will be described below in further details with reference to the drawings.

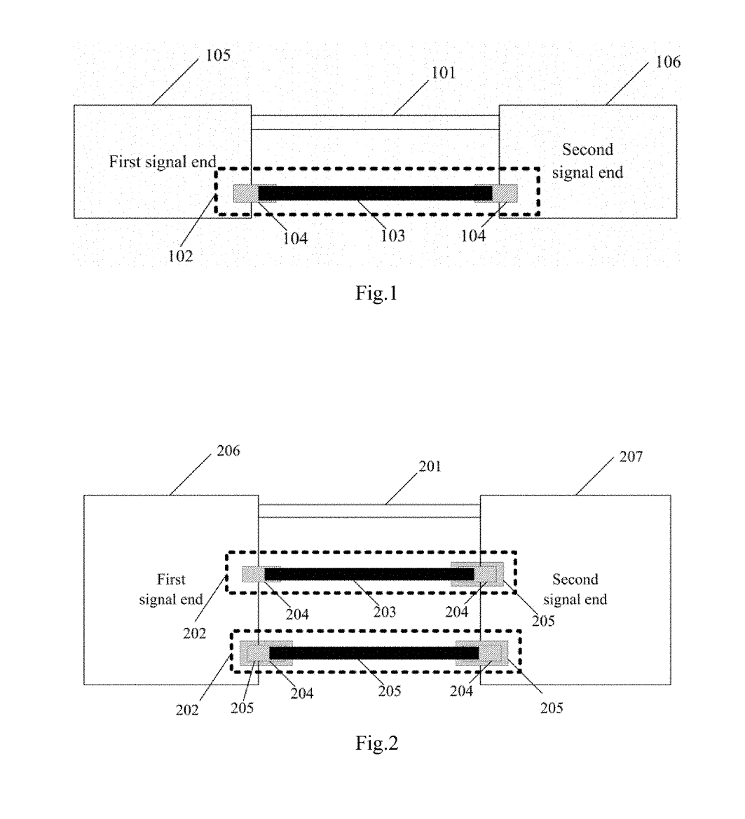

As illustrated in FIG. 1, some embodiments of the application provides a connection structure including a connection line 101, and at least one redundant connection line 102. The redundant connection line 102 includes a redundant connection section 103 and two connection ends 104, where the redundant connection section 103 partially overlaps with the two connection ends 104;

The connection line 101 is electrically connected with a first signal end 105 and a second signal end 106;

The connection ends 104 partially overlap with the first signal end 105 and the second signal end 106 respectively.

The redundant connection line is not connected directly with the two signal ends, and only if the connection line is damaged, then the redundant connection line will be connected with the two signal ends by burning the entire insulation layers, or depositing a conductive thin film, between the connection ends and the signal ends, so that if the connection line fails, then the redundant connection line may be used instead of the connection line.

It shall be noted that the redundant connection section may partially overlap with the two connection ends with or without being connected therewith, and if there are insulation layers between the connection ends and the redundant connection section, then the redundant connection section may be connected with the connection ends through the insulation layers, or may be electrically connected therewith.

The signal ends may partially overlap with the connection ends with or without being connected therewith, and if there are insulation layers between the connection ends and the signal ends, then the signal ends may be connected with the connection ends through the insulation layers, or may be electrically connected therewith. The signal terminals may be connected with the connection ends, and the connection ends may be connected with the redundant connection section, in any appropriate manner as long as the redundant connection line is not connected with the two signal ends.

All of the first signal end, the second signal end, the connection line, and the redundant connection section may be made of the same metal material with the thickness of 0.01 to 1 micrometer by forming their patterns in a photolithograph process of the same layer; the metal material may be selected from Cu, Al, Mo, Ti, Cr, W, Nd, Nb, etc., or may be an alloy of these metal materials structured in one or more layers, e.g., Mo\Al\Mo, Ti\Al\Ti, Ti\Cu\Ti, Mo\Cu\Ti, etc.; the width of the connection ends may range from 1 to 50 micrometers, the length of the connection ends may range from 1 to 50 micrometers, and the thickness of the connection ends may range from 0.01 to 1 micrometer, and the connection ends may be made of a metal material selected from Cu, Al, Mo, Ti, Cr, W, Nd, Nb, etc., or may be an alloy of these metal materials structured in one or more layers, e.g., Mo\Al\Mo, Ti\Al\Ti, Ti\Cu\Ti, Mo\Cu\Ti, etc.

The material of the insulation layer may be selected from silicon nitride, silicon oxide, silicon oxynitride, a compound of silicon nitride and silicon nitride, and alumina, or may be another organic/inorganic insulation medium with some dielectric constant.

The number of redundant connection lines may be more than one, and as illustrated in FIG. 2, a connection structure includes a connection line 201, and two redundant connection lines 202, each of which includes a redundant connection section 203 and two connection ends 204; where one of the connection ends 204 of one of the redundant connection lines 202 is provided with an insulation layer 205, and both of the connection ends 204 of the other redundant connection line 202 are provided with an insulation layer 205, and the redundant connection sections 203 partially overlap with the two connection ends 204;

The connection line 201 is electrically connected with a first signal end 206 and a second signal end 207;

The connection ends 204 partially overlap with the first signal end 206 and the second signal end 207 respectively.

Given one of the redundant connection lines, there are a case that the insulation layer is attached above or below only one of the connection ends, and a case that the insulation layers are attached above or below both of the connection ends, which will be described below in brief respectively.

In the first case, the insulation layer is attached above or below only one of the connection ends in the redundant connection line.

The insulation layer is attached above or below one of the connection ends so that there is the insulation layer between the connection end and the signal end.

The redundant connection section is connected with one of the signal ends through the insulation layer of the connection end where the insulation layer is attached, and electrically connected with the other signal end through the connection end where no insulation layer is attached.

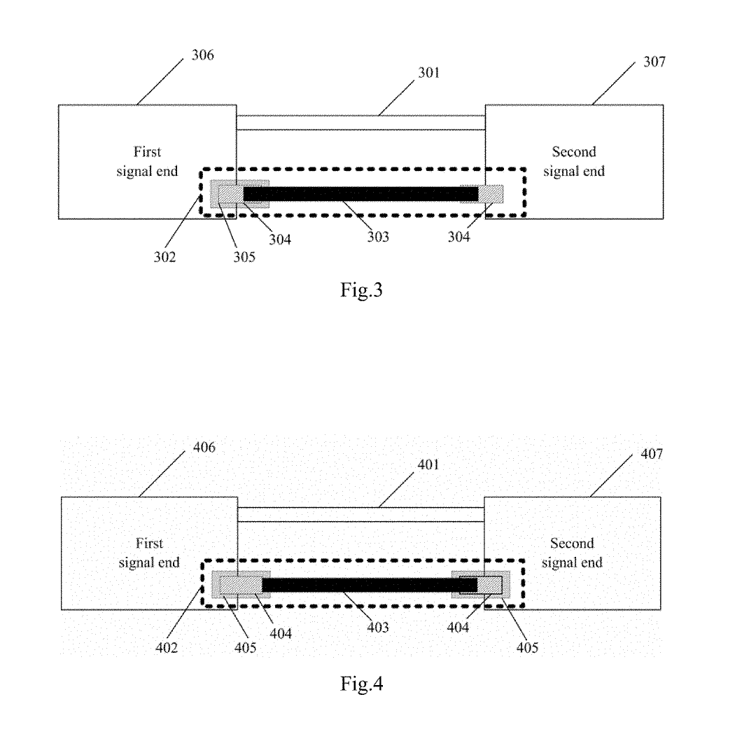

As illustrated in FIG. 3, a connection structure includes a connection line 301, and a redundant connection line 302 including a redundant connection section 303 and two connection ends 304, where an insulation layer 305 is attached above one of the connection ends so that there is the insulation layer 305 between the connection end and a first signal end 306, and the redundant connection section 303 partially overlaps with the two connection ends 304;

The connection line 301 is electrically connected with the first signal end 306 and a second signal end 307;

The redundant connection section 303 is connected with the first signal end 306 through the insulation layer 305 of the connection end 304 where the insulation layer 305 is attached, and electrically connected with the second signal end 307 through the connection end 304 where no insulation layer is attached.

It shall be noted that the insulation layer attached at the connection end may alternatively be not connected with the first signal end, but the connection end may partially overlap with the first signal end without being connected therewith.

In the second case, insulation layers are attached at both of the connection ends of the redundant connection line;

An insulation layer is attached above or below each connection end so that there is the insulation layer between the connection ends and the signal ends.

The redundant connection section is connected respectively with the first signal end and the second signal end through the insulation layers above or below the connection ends.

As illustrated in FIG. 4, a connection structure includes a connection line 401, and a redundant connection line 402 including a redundant connection section 403 and two connection ends 404, where insulation layers 405 are attached below the two connection ends so that there are the insulation layers 405 between the two connection ends and the two signal ends, and the redundant connection section 403 partially overlaps with the two connection ends 404;

The connection line 401 is electrically connected with a first signal end 406 and a second signal end 407;

The redundant connection section 403 is connected respectively with the first signal end 406 and the second signal end 407 through the insulation layers of the connection ends 404.

It shall be noted that the insulation layer attached at the connection end may alternatively be not connected with the first signal end, but the connection end may partially overlap with the first signal end without being connected therewith.

Alternatively one of the two connection ends may be connected with the signal end through the insulation layer attached at the connection end, and the other connection end may partially overlap with the signal end without being connected therewith.

In a practical application, a display panel includes a number of layers between which there may be insulation layers so that there may be the insulation layers above or below signal ends, connection lines, and redundant connection sections at the different layers. At this time, connection ends of redundant connection lines shall partially overlap with the signal ends, that is, the connection ends of the redundant connection lines shall partially overlap with the signal ends with or without being connected the signal ends. In this case, the connection ends of the redundant connection lines may be connected through through-holes so that the connection ends of the redundant connection lines partially overlap with the signal ends, that is, the at least one connection end is connected with the signal end through a through-hole, or the connection ends of the redundant connection lines may be connected otherwise as long as the connection ends of the redundant connection lines partially overlap with the signal ends.

If the connection ends are connected through through-holes, then there may be a case that only one of the connection ends is connected with one of the signal ends through a through-hole, and a case that both of the connection ends are connected with the signal ends through through-holes, which will be described below in brief respectively.

In the first case, only one of the connection ends is connected with one of the signal ends through a through-hole.

If there is an insulation layer attached on one of the two signal ends so that there is the insulation layer between the connection end of the redundant connection line, and the signal end, then the connection end of the redundant connection line will be connected with the signal end where the insulation layer is attached, through a through-hole, that is, the through-hole structure will be formed in the insulation layer on the signal end where the insulation layer is attached; and the other connection end of the redundant connection line may be electrically connected with the other signal end, or may partially overlap therewith without being connected therewith.

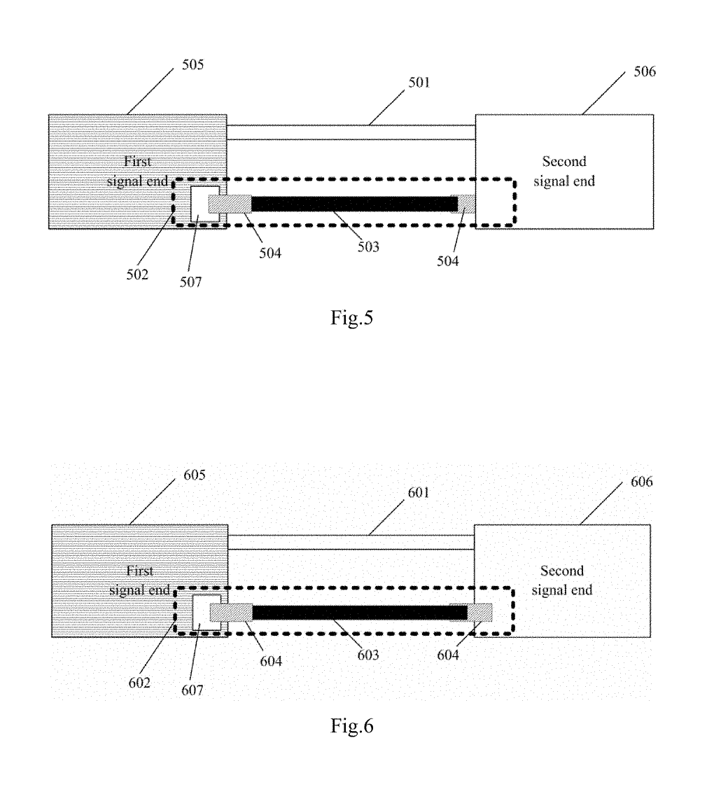

As illustrated in FIG. 5, a connection structure includes a connection line 501, and a redundant connection line 502 including a redundant connection section 503 and two connection ends 504, where the redundant connection section 503 partially overlaps with the two connection ends 504;

There is an insulation layer attached on the first signal end 505;

The connection line 501 is electrically connected with a first signal end 505 and a second signal end 506;

A through-hole structure 507 is formed in the insulation layer on the first signal end 505;

One connection end 504 is electrically connected with the first signal end 505 through the through-hole structure 507;

The other connection end 504 is electrically connected with the second signal end 506.

It shall be noted that in the embodiment illustrated in FIG. 5, both of the connection ends are electrically connected with the signal ends, and in order to disable the two signal ends to connect with the redundant connection line, the redundant connection section may partially overlap with at least one of the two connection ends without being connected therewith.

As illustrated in FIG. 6, a connection structure includes a connection line 601, and a redundant connection line 602 including a redundant connection section 603 and two connection ends 604, where the redundant connection section 603 partially overlaps with the two connection ends 604;

There is an insulation layer attached on a first signal end 605;

The connection line 601 is electrically connected with the first signal end 605 and a second signal end 606;

A through-hole structure 607 is formed in the insulation layer on the first signal end 605;

One connection end 604 is electrically connected with the first signal end 605 through the through-hole structure 607;

The other connection end 604 partially overlaps with the second signal end 606 without being connected therewith.

It shall be noted that in embodiments illustrated in FIG. 6, one of the connection ends is not connected with one of the signal ends so that the redundant connection line is not connected with the signal end, and the redundant connection section may partially overlap with the two connection ends with or without being connected therewith.

In the second case, both of the connection ends are connected with the signal ends through through-holes.

If there are insulation layers attached on both of the signal ends, then the connection ends of the redundant connection line will be connected with the signal ends where the insulation layers are attached, through through-holes, that is, the through-hole structures are formed in the insulation layers on the signal ends.

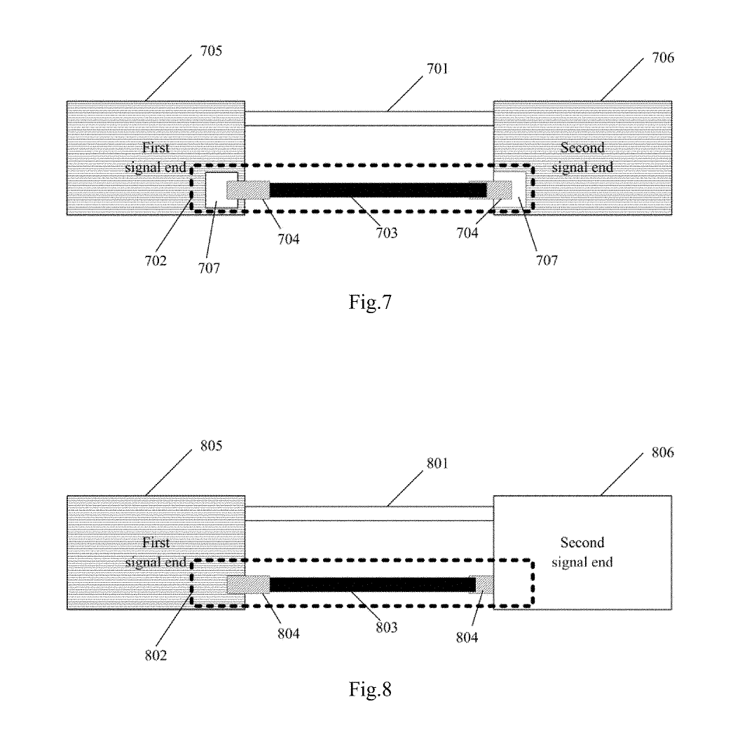

As illustrated in FIG. 7, a connection structure includes a connection line 701, and a redundant connection line 702 including a redundant connection section 703 and two connection ends 704, where the redundant connection section 703 partially overlaps with the two connection ends 704;

There are insulation layers attached on a first signal end 705 and a second signal end 706;

The connection line 701 is electrically connected with the first signal end 705 and the second signal end 706;

A through-hole structure 707 is formed in the insulation layer on the first signal end 705;

Another through-hole structure 707 is formed in the insulation layer on the second signal end 706;

One connection end 704 is electrically connected with the first signal end 705 through the through-hole structure 707;

The other connection end 704 is electrically connected with the second signal end 706 through another through-hole structure 707.

It shall be noted that in embodiments illustrated in FIG. 7, both of the connection ends are electrically connected with the signal ends, and in order to disable the two signal ends to connect with the redundant connection line, the redundant connection section may partially overlap with at least one of the two connection ends without being connected therewith.

There will be also two cases that the connection ends partially overlap with the signal ends without being connected therewith through any through-holes, that is, a case that only one of the connection ends partially overlaps with one of the signal ends without being connected with therewith, and a case that both of the connection ends partially connected with the signal ends, which will be described below in brief respectively.

In the first case, only one of the connection ends partially overlaps with one of the signal ends without being connected with therewith.

If there is an insulation layer attached on one of the two signal ends, then there will be the insulation layer between one connection end of the redundant connection line, and the signal end, and this connection end of the redundant connection line may partially overlap with the signal end where the insulation layer is attached, without being connected therewith; and the other connection end of the redundant connection line may be electrically connected with the other signal end, or may partially overlap therewith while being connected therewith.

As illustrated in FIG. 8, a connection structure includes a connection line 801, and a redundant connection line 802 including a redundant connection section 803 and two connection ends 804, and the redundant connection section 803 partially overlaps with the two connection ends 804;

There is an insulation layer attached on a first signal end 805;

The connection line 801 is electrically connected with the first signal end 805 and a second signal end 806;

One connection end 804 partially overlaps with the first signal end 805 without being connected therewith;

The other connection end 804 is electrically connected with the second signal end 806.

It shall be noted that in embodiments illustrated in FIG. 8, one of the connection ends is not connected with one of the signal ends, and in order to disable the redundant connection line to connect with the two signal ends, the redundant connection section may partially overlap with the two connection ends with or without being electrically connected therewith.

In fact, one of the connection ends is electrically connected with one of the signal ends so that the redundant connection section of the redundant connection line is connected directly with the signal end, that is, alternatively there may be only one connection end of the redundant connection line.

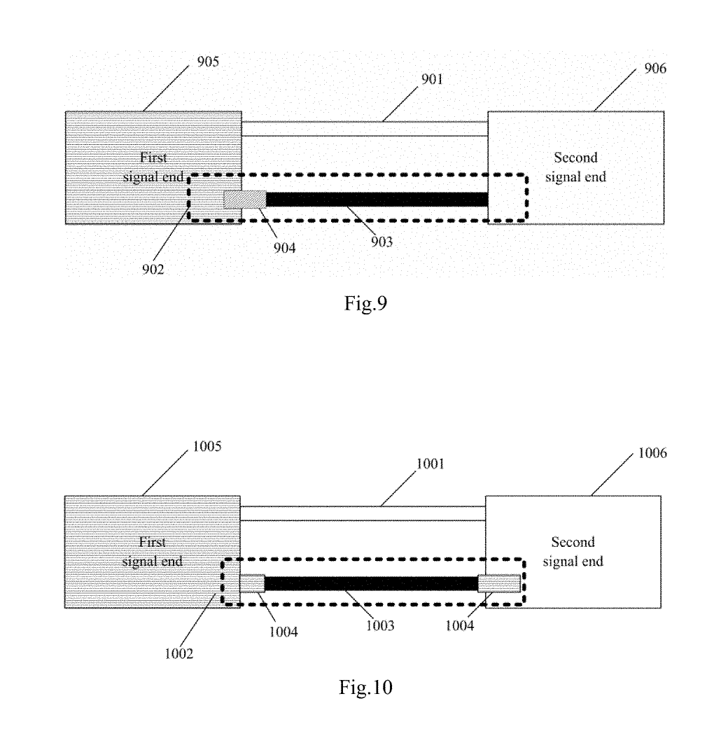

As illustrated in FIG. 9, a connection structure includes a connection line 901, and a redundant connection line 902 including a redundant connection section 903 and a connection end 904, where the redundant connection section 903 partially overlaps with the connection end 904;

There is an insulation layer attached on a first signal end 905;

The connection line 901 is electrically connected with the first signal end 905 and the second signal end 906;

The connection end 904 partially overlaps with the first signal end 905 without being connected therewith;

The redundant connection section 903 is electrically connected with the second signal end 906.

It shall be noted that in embodiments illustrated in FIG. 9, the connection end is not connected with one of the signal ends so that the redundant connection line is not connected with the connection end, and the redundant connection section may partially overlap with the two connection ends while being electrically connected therewith, or may partially overlap therewith without being connected therewith.

As illustrated in FIG. 10, a connection structure includes a connection line 1001, and a redundant connection line 1002 including a redundant connection section 1003 and two connection ends 1004, where the redundant connection section 1003 partially overlaps with the two connection ends 1004;

There is an insulation layer attached on a first signal end 1005 and the redundant connection line 1002;

The connection line 1001 is electrically connected with the first signal end 1005 and a second signal end 1006;

One connection end 1004 is electrically connected with the first signal end 1005; and

The other connection end 1004 partially overlaps with the second signal end 1006 without being connected therewith.

It shall be noted that in embodiments illustrated in FIG. 10, one of the connection ends is not connected with one of the signal ends so that the redundant connection line is not connected with the signal end, and the redundant connection section may partially overlap with the two connection ends with being electrically connected therewith, or may partially overlap therewith without being connected therewith.

In fact, one of the connection ends is electrically connected with one of the signal ends so that the redundant connection section of the redundant connection line is connected directly with the signal end, that is, alternatively there may be only one connection end of the redundant connection line.

As illustrated in FIG. 11, a connection structure includes a connection line 1101, and a redundant connection line 1102 including a redundant connection section 1103 and a connection end 1104, where the redundant connection section 1103 partially overlaps with the connection end 1104;

There is an insulation layer attached on a first signal end 1105 and the redundant connection line 1102;

The connection line 1101 is electrically connected with the first signal end 1105 and the second signal end 1106;

The connection end 1104 partially overlaps with the first signal end 1105 without being connected therewith;

The redundant connection section 1103 is electrically connected with the second signal end 1106.

In the second case, both of the connection ends partially overlap with the signal ends without being connected therewith.

If there are insulation layers attached on both of the signal ends, and the connection ends of the redundant connection line are to be connected with the signal ends where the insulation layers are attached, then the connection ends of the redundant connection line may partially overlap with the signal ends where the insulation layers are attached, without being connected therewith.

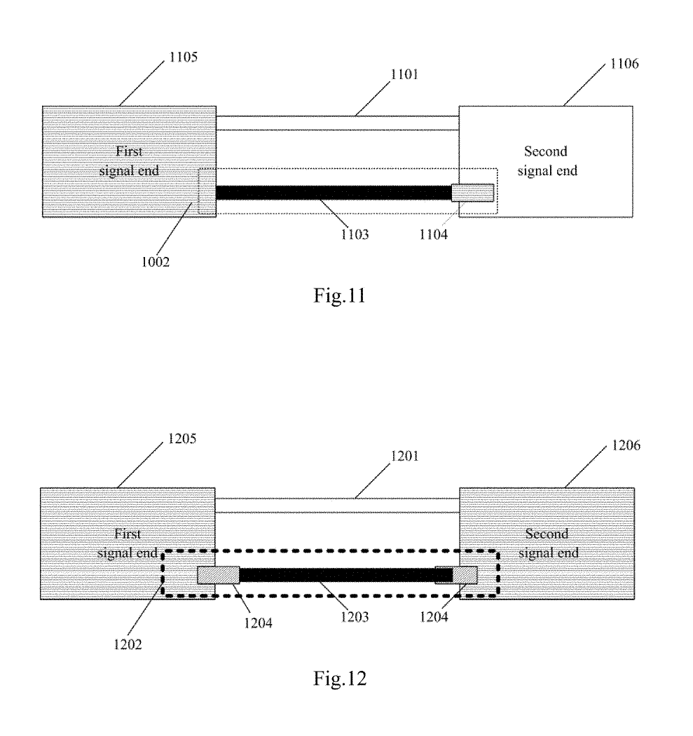

As illustrated in FIG. 12, a connection structure includes a connection line 1201, and a redundant connection line 1202 including a redundant connection section 1203 and two connection ends 1204, where the redundant connection section 1203 partially overlaps with the two connection ends 1204;

There are insulation layers attached on a first signal end 1205 and a second signal end 1206;

The connection line 1201 is electrically connected with the first signal end 1205 and the second signal end 1206;

One connection end 1204 partially overlaps with the first signal end 1205 without being connected therewith.

The other connection end 1204 partially overlaps with the second signal end 1206 without being connected therewith.

It shall be noted that in embodiments illustrated in FIG. 12, both of the connection ends are disconnected from the signal ends so that the two signal ends are not connected with the redundant connection line, and the redundant connection section may partially overlap with the two connection ends 504 without being connected therewith, or may partially overlap therewith while being connected therewith.

In a practical application, a display panel includes a number of layers between which there may be insulation layers so that there may be the insulation layers above or below signal ends, connection lines, and redundant connection sections at the different layers. At this time, redundant connection sections of redundant connection lines shall partially overlap with connection ends, that is, the redundant connection sections of the redundant connection lines shall partially overlap with the connection ends without being connected therewith, or the redundant connection sections of the redundant connection lines shall partially overlap with the connection ends with being electrically connected therewith. In this case, through-holes can be used so that the redundant connection sections of the redundant connection lines partially overlap with the connection ends by the through-holes, that is, the at least one connection end is connected with the redundant connection section through a through-hole, or the through-holes may not be used otherwise as long as the connection ends partially overlap with the redundant connection section.

The two cases that the redundant connection section is connected with one of the connection ends through a through-hole, and that the redundant connection is connected with both of the connection ends through through-holes will be described below in brief respectively.

In the first case, the redundant connection section is connected with one of the connection ends through a through-hole.

If there is an insulation layer covering above and/or below the redundant connection section so that there is the insulation layer between the redundant connection section and one of the connection ends, then the connection end will be connected with the redundant connection section through a through-hole, that is, the through-hole structure will be formed in the insulation layer on the redundant connection section.

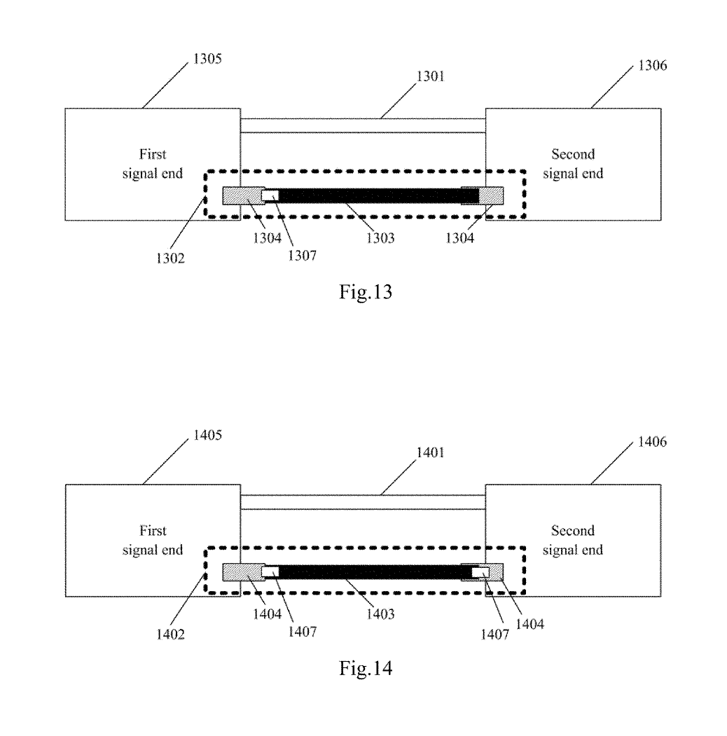

As illustrated in FIG. 13, a connection structure includes a connection line 1301, and a redundant connection line 1302 including a redundant connection section 1303 and two connection ends 1304, where there is an insulation layer attached on the redundant connection section 1303, and a through-hole structure 1307 is formed in the insulation layer on one end of the redundant connection section 1303;

The redundant connection section 1303 is electrically connected with one of the connection ends 1304 through the through-hole structure 1307;

The redundant connection section 1303 partially overlaps with the other connection end 1304;

The connection line 1301 is electrically connected with a first signal end 1305 and a second signal end 1306;

The connection ends 1304 partially overlap with the first signal end 1305 and the second signal end 1306 respectively.

It shall be noted that in embodiments illustrated in FIG. 13, the redundant connection section is electrically connected with one of the connection ends, and in order to disable the two signal ends to connect with the redundant connection line, the redundant connection section may partially overlap with the other one of the two connection ends without being connected therewith, or the connection end may partially overlap with at least one of the first signal end and the second signal end without being connected therewith.

In the second case, the redundant connection section is connected with both of the connection ends through through-holes.

If there is an insulation layer covering above and/or below the redundant connection section so that there is the insulation layer between the redundant connection section and the connection ends, then the connection ends will be connected with the redundant connection section through through-holes, that is, the through-hole structures will be formed in the insulation layer on the redundant connection section.

As illustrated in FIG. 14, the connection structure includes a connection line 1401, and a redundant connection line 1402 including a redundant connection section 1403 and two connection ends 1404, where there is an insulation layer attached on the redundant connection section 1403, and through-holes 1407 are formed in the insulation layer on both ends of the redundant connection section 1403;

The redundant connection section 1403 is electrically connected with one of the connection ends 1404 through one of the through-holes 1407;

The redundant connection section 1403 is electrically connected with the other connection end 1404 through the other one of through-holes 1407;

The connection line 1401 is electrically connected with a first signal end 1405 and a second signal end 1406;

The connection ends 1404 partially overlap respectively with the first signal end 1405 and the second signal end 1406.

It shall be noted that the first signal end may be one end of a signal line selected from a gate line, a data line, a common electrode line, a power source line, a clock signal line, a test signal line, and a transistor control signal line, in an array substrate.

The width of the signal line may range from 1 to 50 micrometers, the width of the first signal end may range from 1 to 50 micrometers, and the first signal end may be a part of the signal line, or may be such a separate part which is connected with the signal line and has a different length and width, where the length thereof may range from 1 to 50 micrometers.

The second signal end may be one end of a signal transmission line selected from a lead for transmitting a gate scan signal, a lead for transmitting voltage signal of display data, a lead for transmitting common voltage, a lead for transmitting power source voltage, a lead for transmitting a test signal of an array substrate, a lead for transmitting a clock signal, and a lead for transmitting a control signal of a transistor.

The width of the signal transmission line may range from 1 to 50 micrometers, the width of the second signal end may range from 1 to 50 micrometers, and the second signal end may be a part of the transmission signal line, or may be such a separate part which is connected with the signal line and has a different length and width, where the length thereof may range from 1 to 50 micrometers.

The signal line and the signal transmission line will not be limited to the examples above, but in a practical application, any signal line and signal transmission line where there is a connection line between signal ends of the signal line and the signal transmission line will be applicable to the embodiments of the application.

The connection line may be electrically connected directly with the signal ends, or may be electrically connected with the signal ends through through-holes, that is, the connection line is electrically connected with at least one of the first signal end and the second signal end through a through-hole.

If the connection line is electrically connected with the signal ends through through-holes, then there may be two cases that the connection line is electrically connected with one of the signal ends through a through-hole, and that the connection line is connected with both of the signal ends through through-holes, which will be described below in brief respectively.

In the first case, the connection line is electrically connected with one of the signal ends through a through-hole.

If there is an insulation layer attached on one of the signal ends, then the connection line will be connected with the signal end where the insulation layer is attached, through a through-hole, that is, the through-hole structure will be formed on the insulation layer of the signal end where the insulation layer is attached.

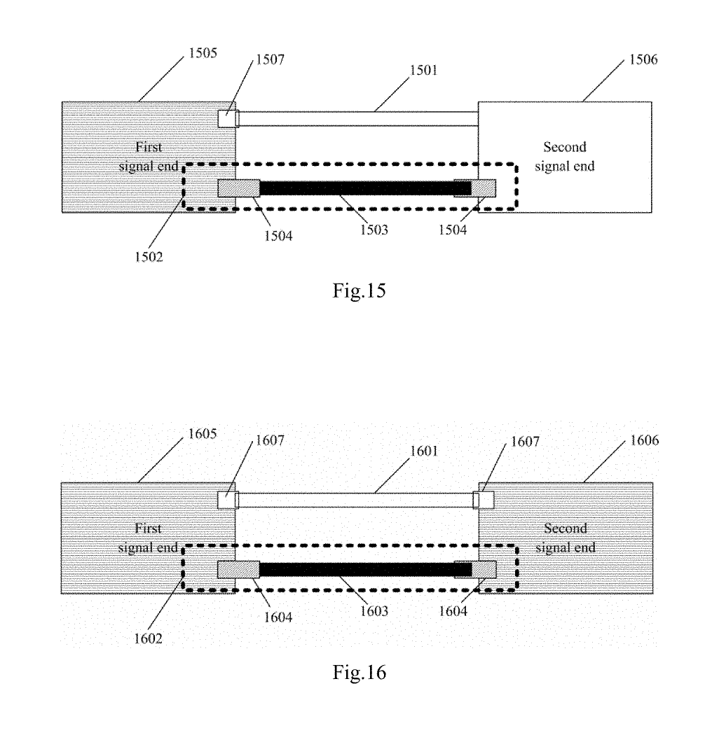

As illustrated in FIG. 15, a connection structure includes a connection line 1501, and a redundant connection line 1502 including a redundant connection section 1503 and two connection ends 1504, where the redundant connection section 1503 partially overlaps with the two connection ends 1504;

There is an insulation layer attached on a first signal end 1505, and a through-hole structure 1507 is formed in the insulation layer on the first signal end 1505;

The connection line 1501 is electrically connected with the first signal end 1506 through the through-hole structure 1507;

The connection line 1501 is electrically connected with the second signal end 1506;

The connection ends 1504 partially overlap with the first signal end 1505 and the second signal end 1506 respectively.

In the second case, the connection line is electrically connected with both of the signal ends through through-holes.

If there are insulation layers attached on the two signal ends, then the connection line will be connected with the signal ends where the insulation layers are attached, through through-holes, that is, the through-hole structures will be formed in the insulation layers on the signal ends where the insulation layers are attached.

As illustrated in FIG. 16, a connection structure includes a connection line 1601, and a redundant connection line 1602 including a redundant connection section 1603 and two connection ends 1604, where the redundant connection section 1603 partially overlaps with the two connection ends 1604;

There are insulation layers attached on a first signal end 1605 and a second signal end 1606, and through-hole structures 1607 are formed in the insulation layers on the first signal end 1605 and the second signal end 1606;

The connection line 1601 is electrically connected with the first signal end 1605 through one of the through-hole structures 1607;

The connection line 1601 is electrically connected with the second signal end 1606 through the other one of the through-hole structures 1607;

The connection ends 1604 partially overlap with the first signal end 1605 and the second signal end 1606 respectively.

It shall be noted that the connection mode of the connection line with the signal ends will not be directly related to the connection mode of the redundant connection line with the signal ends, but in a practical application, their corresponding connection modes may be particularly selected as needed.

Common combinations of the connection mode of the connection line with the signal ends, and the connection mode of the redundant connection line with the signal ends will be exemplified below.

In a first combination, the connection line is electrically connected respectively with the two signal ends through through-holes, and there are no through-hole structures between the redundant connection and the signal ends.

As illustrated in FIG. 16, there are insulation layers on the first signal end 1605 and the second signal end 1606, and through-hole structures 1607 are formed in the insulation layers on the first signal end 1605 and the second signal end 1606;

The connection line 1601 is electrically connected with the first signal end 1605 through one of the through-hole structures 1607;

The connection line 1601 is electrically connected with the second signal end 1606 through the other one of the through-hole structures 1607;

The connection ends 1604 of the redundant connection line are not connected with the first signal end 1605 and the second signal end 1606 through through-hole structures.

In a second combination, the connection line is electrically connected with one of the two signal ends through a through-hole, and connected directly with the other signal end, and there are no through-hole structures between the redundant connection and the signal ends.

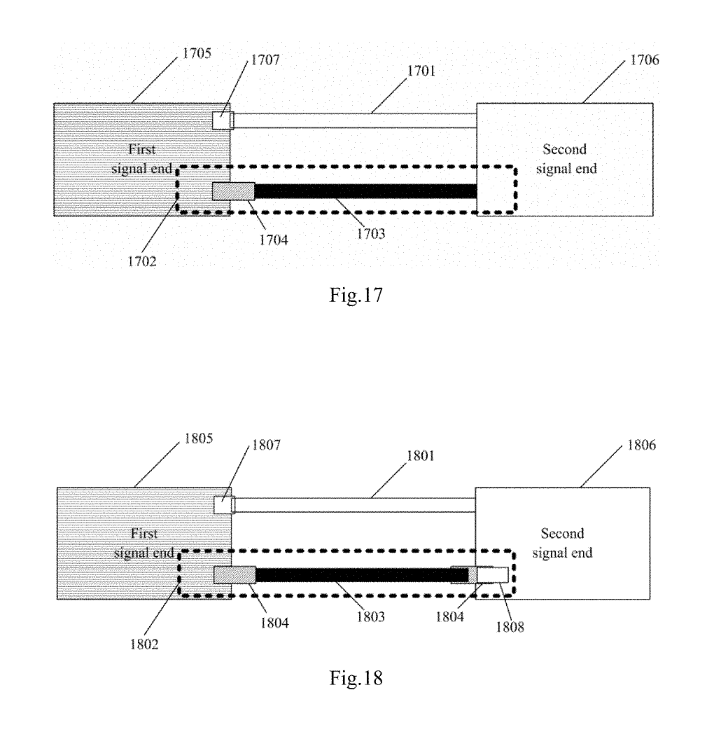

As illustrated in FIG. 17, a connection structure includes a connection line 1701, and a redundant connection line 1702 including a redundant connection section 1703 and a connection end 1704, where the redundant connection section 1703 partially overlaps with the connection end 1704;

There is an insulation layer attached on a first signal end 1705, and a through-hole structure 1707 is formed in the insulation layer on the first signal end 1705;

The connection line 1701 is electrically connected with the first signal end 1705 through the through-hole structure 1707;

The connection line 1701 is electrically connected with a second signal end 1706;

The connection end 1704 partially overlaps with the first signal end 1705 without being connected therewith;

The redundant connection section 1703 is electrically connected with the second signal end 1706.

It shall be noted that if there are no insulation layers between the connection ends of the redundant connection line, and the signal ends, then the connection ends may be electrically connected with the signal ends; or they may be not connected, but metal sheets may be added to the signal ends and the connection ends so that the metal sheets partially overlap with both the signal ends and the connection ends without any contact therewith. If the redundant connection line needs to be used instead of the connection line, then the metal sheets may be electrically connected respectively with the signal ends and the connection ends so that the signal ends are connected with the connection ends through the metal sheets.

As illustrated in FIG. 18, a connection structure includes a connection line 1801, and a redundant connection line 1802 including a redundant connection section 1803 and two connection ends 1804, where the redundant connection section 1803 partially overlaps with the two connection ends 1804;

There is an insulation layer attached on a first signal end 1805, and a through-hole 1807 is formed on the insulation layer on the first signal end 1805;

The connection line 1801 is electrically connected with the first signal end 1805 through the through-hole structure 1807;

The connection line 1801 is electrically connected with a second signal end 1806;

One of the connection ends 1804 partially overlaps with the first signal end 1805.

There is a metal sheet 1808 on the second signal 1806 and the other connection end 1804, the metal sheet 1808 is located at the same layer as the first signal end 1805, and the metal sheet 1808 partially overlaps with both the second signal end 1806 and the connection end 1804 without any contact therewith.

In a third combination, the connection line is electrically connected with the two signal ends, and the connection ends of the redundant connection line are connected with the two signal ends through through-holes.

If there are insulation layers above or below the signal ends, the connection line, and the redundant connection line, then as illustrated in FIG. 7, the connection line 701 is electrically connected with the first signal end 705 and the second signal end 706;

The redundant connection section 703 is connected with the first signal end 705 through one of the connection ends 704 and one of the through-hole structures 707;

The redundant connection section 703 is connected with the second signal end 706 through the other one of the connection ends 704 and the other one of the through-hole structures 707.

In a fourth combination, the connection line is electrically connected with the two signal ends, and the connection ends of the redundant connection line are connected with the redundant connection section through through-holes.

If there are insulation layers above or below the signal ends, the connection line, and the redundant connection line, then as illustrated in FIG. 14, the connection line 1401 is electrically connected with the first signal end 1405 and the second signal end 1406;

The redundant connection section 1403 is connected with one of the connection ends 1404 through one of the through-hole structures 1407;

The redundant connection section 1403 is connected with the other connection end 1404 through the other one of the through-hole structures 1407;

The connection end 1404 partially overlaps respectively with the first signal end 1405 and the second signal end 1406.

Any one or more of the connection structures described above may be applicable to an array substrate, that is, the array substrate may include any one or more of the connection structures described above.

The array substrate including any one or more of the connection structures described above may also be a part of a display device, that is, the display device may include the array substrate described above.

Evidently those skilled in the art can make various modifications and variations to the application without departing from the spirit and scope of the application. Accordingly the application is also intended to encompass these modifications and variations thereto so long as the modifications and variations come into the scope of the claims appended to the application and their equivalents.

1. A connection structure, comprising a connection line, and at least one redundant connection line comprising a redundant connection section and two connection ends, wherein the redundant connection section partially overlaps with the two connection ends;
the connection line is electrically connected with a first signal end and a second signal end; and
the connection ends partially overlap respectively with the first signal end and the second signal end.

2. The connection structure according to claim 1, wherein there is an insulation layer attached on at least one of the first signal end and the second signal end.

3. The connection structure according to claim 1, wherein there is an insulation layer attached above or below the redundant connection section of the redundant connection line.

4. The connection structure according to claim 1, wherein there is an insulation layer attached above or below at least one of the two connection ends of the redundant connection line.

5. The connection structure according to claim 4, wherein when there is an insulation layer attached above or below one of the connection ends of the redundant connection line,
the connection ends partially overlap with the first signal end and the second signal end respectively in such a way that:
the insulation layer at the connection end above or below which the insulation layer is attached is connected with one of the signal ends; or
the connection end above or below which the insulation layer is attached partially overlaps with one of the signal ends without being connected therewith; and
the connection end to which no insulation layer is attached is electrically connected with the other one of the signal ends.

6. The connection structure according to claim 4, wherein when there are insulation layers attached above or below the two connection ends of the redundant connection line,
the connection ends partially overlap with the first signal end and the second signal end respectively in such a way that:
the insulation layers above or below the connection ends are connected respectively with the first signal end and the second signal end; or
the connection ends partially overlap respectively with the first signal end and the second signal end without being connected therewith; or
one of the connection ends above or below which the insulation layer is attached is connected with one of the first signal end and the second signal end, and the other one of the connection end above or below which the insulation layer is attached partially overlaps with the other one of the first signal end and the second signal end without being connected therewith.

7. The connection structure according to claim 2, wherein at least one of the connection ends is connected with the signal end through a through-hole.

8. The connection structure according to claim 2, wherein one of the connection ends is connected with the insulation layer at the signal end to which the insulation layer is attached; or
one of the connection ends partially overlaps with the signal end to which the insulation layer is attached, without being connected therewith.

9. The connection structure according to claim 3, wherein the redundant connection section is connected with at least one of the connection ends through a through-hole.

10. The connection structure according to claim 1, wherein the first signal end is one end of a signal line selected from a gate line, a data line, a common electrode line, a power source line, a clock signal line, a test signal line, and a transistor control signal line, in an array substrate.

11. The connection structure according to claim 1, wherein the second signal end is one end of a signal transmission line selected from a lead for transmitting a gate scan signal, a lead for transmitting voltage signal of display data, a lead for transmitting common voltage, a lead for transmitting power source voltage, a lead for transmitting a test signal of an array substrate, a lead for transmitting a clock signal, and a lead for transmitting a control signal of a transistor.

12. The connection structure according to claim 1, wherein the connection line is further electrically connected with the first signal end and the second signal end in such a way that:
the connection line is electrically connected with at least one of the first signal end and the second signal end through a through-hole.

13. An array substrate, comprising the connection structure according to claim 1.

14. A display device, comprising the array substrate according to claim 13.
